(19) United States
(12) Patent Application Publication
(10) Pub. No.: US 2016/0276166 A1
(43) Pub. Date: Sep. 22, 2016

(54) METHOD OF MANUFACTURING SEMICONDUCTOR DEVICE

(71) Applicant: KABUSHIKI KAISHA TOSHIBA, Tokyo (JP)

(72) Inventors: Hiroshi YAMAMOTO, Kuwana (JP); Mitsuhiro OMURA, Kuwana (JP)

(21) Appl. No.: 14/833,706

(22) Filed: Aug. 24, 2015

(30) Foreign Application Priority Data
Mar. 16, 2015 (JP) 2015-51995

(51) Int. Cl. H01L 21/311; H01L 21/02

(52) U.S. Cl. CPC H01L 21/31116; H01L 21/02164; H01L 21/31144; H01L 21/02282; H01L 21/02271

(57) ABSTRACT

In one embodiment, a method of manufacturing a semiconductor device includes forming a first silicon oxide film having a first carbon content above a substrate. The method further includes forming a second silicon oxide film having a second carbon content different from the first carbon content on the first silicon oxide film. The method further includes selectively etching the first or second silicon oxide film by using a gas containing bromine or chlorine.

### CROSS REFERENCE TO RELATED APPLICATION

This application is based upon and claims the benefit of priority from the prior Japanese Patent Application No. 2015-51995, filed on Mar. 16, 2015, the entire contents of which are incorporated herein by reference.

### FIELD

Embodiments described herein relate to a method of manufacturing a semiconductor device.

### BACKGROUND

When a semiconductor device is manufactured, various insulators are used as a layer forming the semiconductor device and a mask layer or a sacrificial layer for etching. Typical examples of such insulators are a silicon oxide film and a silicon nitride film. When the silicon oxide film and the silicon nitride film are formed on a substrate, it is easy to selectively etch one of the silicon oxide film and the silicon nitride film. However, when silicon oxide films of different kinds are formed on the substrate, it is difficult to selectively etch one of these silicon oxide films.

### BRIEF DESCRIPTION OF THE DRAWINGS

FIGS. 1A to 2B are sectional views illustrating a method of manufacturing a semiconductor device of a first embodiment;

FIGS. 3A to 3C are graphs illustrating etching rates in a case where a HBr gas was used in the first embodiment;

FIGS. 4A to 4C are graphs illustrating etching rates in a case where a Cl₂ gas was used in the first embodiment;

FIGS. 5A and 5B are graphs illustrating etching rates in a case where a CF-based gas was used in the first embodiment;

FIGS. 6A to 6C are graphs illustrating etching rates in a case where an O₂ gas was used with a HBr gas in the first embodiment;

FIGS. 7A to 7C are graphs illustrating etching rates in a case where an O₂ gas was used with a HBr gas in the first embodiment;

FIGS. 8A and 8B are graphs illustrating relation between ion energy and etching rates in the first embodiment;

FIGS. 9A and 9B are graphs illustrating relation between ion energy and etching rates in the first embodiment; and

FIGS. 10A and 10B are sectional views illustrating a method of manufacturing a semiconductor device of a second embodiment.

### DETAILED DESCRIPTION

Embodiments will now be explained with reference to the accompanying drawings.

In one embodiment, a method of manufacturing a semiconductor device includes forming a first silicon oxide film having a first carbon content above a substrate. The method further includes forming a second silicon oxide film having a second carbon content different from the first carbon content on the first silicon oxide film. The method further includes selectively etching the first or second silicon oxide film by using a gas containing bromine or chlorine.

### First Embodiment

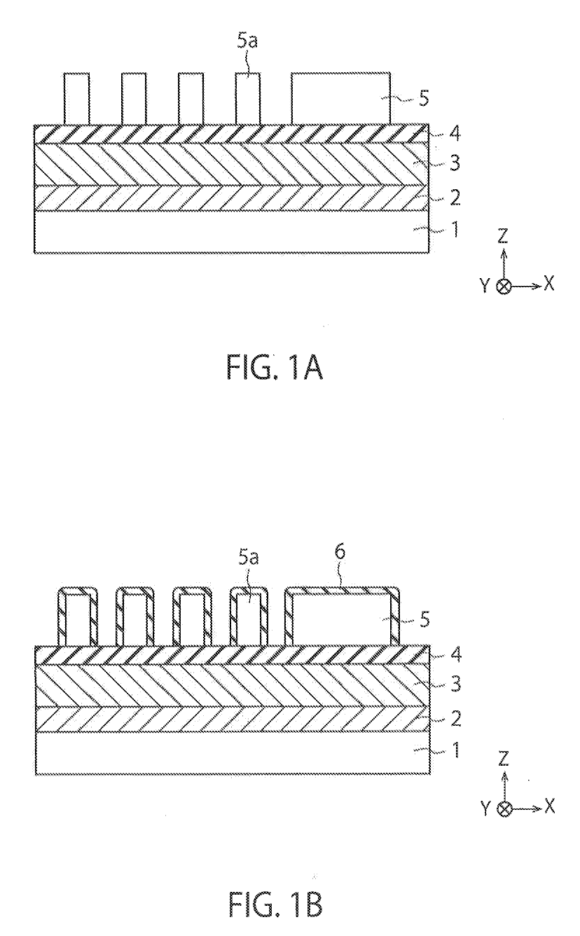

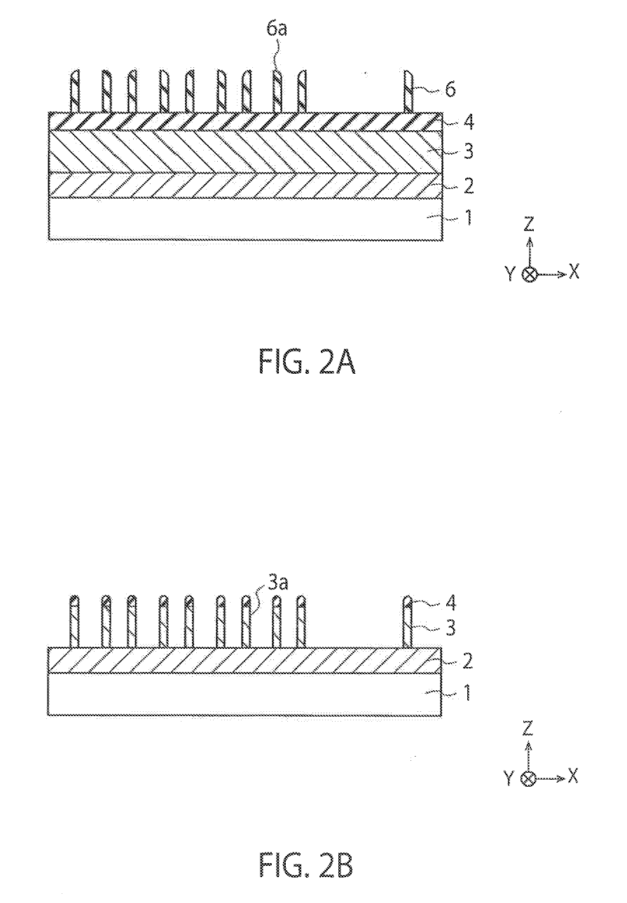

FIGS. 1A to 2B are sectional views illustrating a method of manufacturing a semiconductor device of a first embodiment. In the present method, a double sidewall transfer process is performed. For example, the present method is used to form line and space (L/S) patterns for a NAND flash memory.

First, a first process target film 2, a second process target film 3, a mask layer 4 and a resist film 5 are sequentially formed on a substrate 1 (FIG. 1A). Resist patterns 5a are then formed of the resist film 5 by lithography and etching (FIG. 1A).

An example of the substrate 1 is a semiconductor substrate such as a silicon substrate. FIG. 1A illustrates an X-direction and a Y-direction which are parallel to the surface of the substrate 1 and perpendicular to each other, and a Z-direction perpendicular to the surface of the substrate 1. In the present specification, the +Z-direction is regarded as the upward direction and the −Z-direction is regarded as the downward direction, For example, positional relation between the substrate 1 and the first process target film 2 is expressed as that the substrate 1 is positioned below the first process target film 2. The −Z-direction of the present embodiment may coincide with the direction of gravity or may not coincide with the direction of gravity.

An example of the first process target film 2 is an amorphous silicon layer. The first process target film 2 may be directly formed on the substrate 1 or may be formed on the substrate 1 through another layer.

An example of the second process target film 3 is a carbon film formed by chemical vapor deposition (CVD). The second process target film 3 of the present embodiment is used as a lower core material in the double sidewall transfer process.

An example of the mask layer 4 is a silicon oxide film. Specifically, the mask layer 4 of the present embodiment is a spin-on glass (SOC) film and formed by applying a coating solution for forming the mask layer 4 on the second process target film 3. Therefore, the mask layer 4 of the present embodiment contains carbon which is dissolved from the second process target film 3 into the mask layer 4. Hereafter, a carbon content of the mask layer 4 is referred to as a first carbon content. The first carbon content is a ratio of the total number of the carbon atoms in the mask layer 4 relative to the total number of the atoms in the mask layer 4. The mask layer 4 is an example of a first silicon oxide film.

The resist film 5 may be of positive-type or negative-type. The resist film 5 of the present embodiment is used as an upper core material in the double sidewall transfer process. The resist patterns 5a are an example of a first pattern.

Next, a sidewall film 6 is formed on the whole surface of the substrate 1 (FIG. 1B). As a result, the sidewall film 6 is formed on side faces and upper faces of the resist patterns 5a and an upper face of the mask layer 4. A thickness of the sidewall film 6 of the present embodiment is adjusted to be a value of approximately a pitch of the above-mentioned L/S patterns.

An example of the sidewall film 6 is a silicon oxide film. Specifically, the sidewall film 6 of the present embodiment is a ULT-SiO₂ film formed by CVD as a low-temperature process. The sidewall film 6 of the present embodiment does not contain carbon or contains a slight amount of carbon. Hereafter, a carbon content of the sidewall film 6 is referred to as a second carbon content. The second carbon content is a ratio of the total number of the carbon atoms in the sidewall film 6 relative to the total number of the atoms in the sidewall film 6. The sidewall film 6 is an example of the second silicon oxide film.

The mask layer 4 of the present embodiment contains carbon higher in concentration than the sidewall film 6. Therefore, the second carbon content of the present embodiment is different from the first carbon content, and specifically, lower than the first carbon content. The first carbon content of the present embodiment is 5% or more, preferably, 10% or more. The second carbon content of the present embodiment is less than 5%, preferably, 1% or less. When the sidewall film 6 does not contain carbon, the second carbon content is 0%.

The sidewall film 6 is then processed by etch-back (FIG. 2A). As a result, sidewall patterns 6a are formed on the side faces of the resist patterns 5a. The sidewall patterns 5a are an example of a second pattern. Next, the resist film 5 is removed using plasma (FIG. 2A). An example of the plasma is oxygen plasma.

The mask layer 4 and the second process target film 3 are then etched using the sidewall patterns 6a as a mask (FIG. 2B). As a result, the sidewall patterns 6a are transferred onto the second process target film 3, so that core material patterns 3a are formed of the second process target film 3. In this etching, the sidewall film 6 and the mask layer 4 may be completely removed or may be partially left. In FIG. 2B, the sidewall film 6 is completely removed and the mask layer 4 is partially left.

The etching in FIG. 2B is performed using a gas containing bromine or chlorine. Examples of such gas include a hydrogen bromide (HBr) gas, a hydrogen chloride (HCl) gas, a bromine (Br₂) gas and a chlorine (Cl₂) gas. For example, the etching in FIG. 2B is performed by forming plasma from a mixed gas that contains a gas containing bromine or chlorine and an oxygen (O₂) gas.

As a result of an experiment, when a silicon oxide film was etched using the gas containing bromine or chlorine, it was found that an etching rate of the silicon oxide film increased as the carbon content of the silicon oxide film increased. Therefore, in the etching of FIG. 26, the mask layer 4 (first silicon oxide film) can be selectively etched with the sidewall film 6 (second silicon oxide film) being as a mask. The reason is that the first carbon content is higher than the second carbon content and the etching rate of the mask layer 4 is higher than the etching rate of the sidewall film 6.

In general, etching of a silicon oxide film is performed using a CF-based gas containing C_{X}Fl_{Y}F_{Z} molecules, where C denotes carbon, H denotes hydrogen, F denotes fluorine, X is an integer of one or more, Y is an integer of zero or more, and Z is an integer of one or more. The C atoms in the CF-based gas react with the O atoms in the silicon oxide film. The F atoms in the CF-based gas react with the Si atoms in the silicon oxide film.

On the other hand, since the mask layer 4 of the present embodiment contains carbon, the mask layer 4 can be etched using a gas that does not contain carbon. Therefore, the mask layer 4 of the present embodiment is etched using the gas that does not contain the C_{X}H_{Y}F_{Z} molecules.

Notably, the mask layer 4 of the present embodiment may be etched using a mixed gas that contains the gas containing bromine or chlorine and the CF-based gas. The CF-based gas can be added, for example, for adjusting the etching rate of the mask layer 4. Also in this case, the mole fraction of the CF-based gas in the mixed gas is preferably 5% or less such that the etching selection ratio between silicon oxide films of different kinds does not largely decrease.

After the process in FIG. 2B, sidewall patterns are formed on the side faces of the core material patterns 3a. The first process target film 2 is then etched using the sidewall patterns as a mask. As a result, the sidewall patterns are transferred onto the first process target film 2, so that line patterns are formed of the first process target film 2. In this way, the semiconductor device of the present embodiment is manufactured.

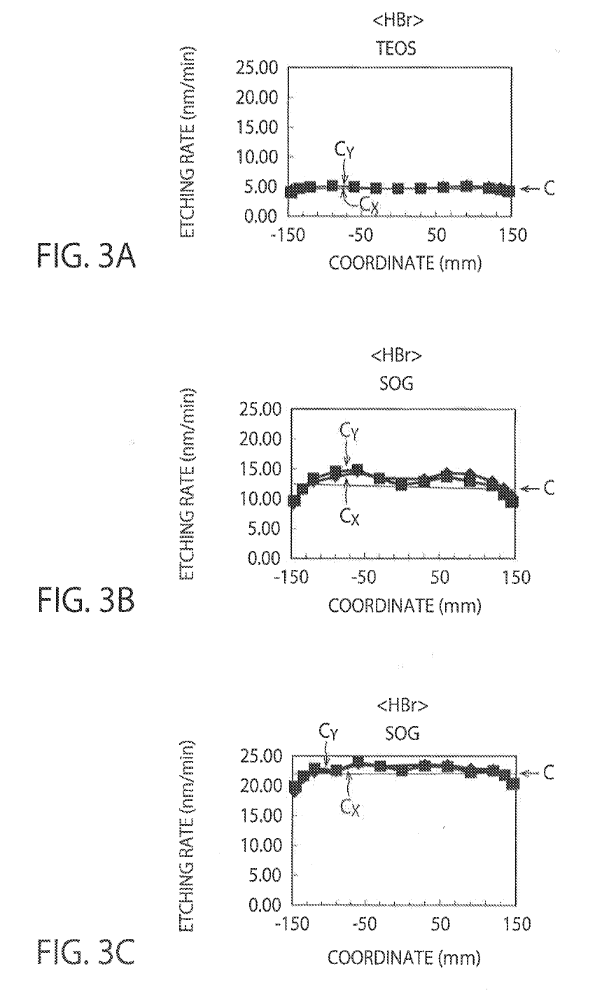

FIGS. 3A to 3C are graphs illustrating etching rates in a case where a HBr gas was used in the first embodiment.

FIG. 3A illustrates the etching rate of a tetraethyl orthosilicate (TEOS) film whose carbon content was several atom % (less than 5 atom %). FIG. 36 illustrates the etching rate of a SOG film whose carbon content was 7 atom %. FIG. 3C illustrates the etching rate of a SOG film whose carbon content was 12 atom %. Etching of these films was performed using the HBr gas.

The horizontal axis in FIG. 3A represents an X-coordinate and a Y-coordinate on the substrate 1, Curves C_{X} and C_{Y} in FIG. 3A respectively represent changes in etching rate at points on the substrate 1 in the X-direction and the Y-direction. A line C in FIG. 3A represents a straight line obtained by approximating the curves C_{X} and C_{Y}. The same holds true for FIGS. 3B and 3C and the following figures.

From FIGS. 3A to 3C, it is apparent that the etching rate of the silicon oxide film increases as the carbon content of the silicon oxide film increases. For example, in a case where the TEOS film in FIG. 3A is used as the sidewall film 6 and the SOG film in FIG. 3C is used as the mask layer 4, the etching selection ratio that is approximately 4 is realized in the etching of FIG. 2B.

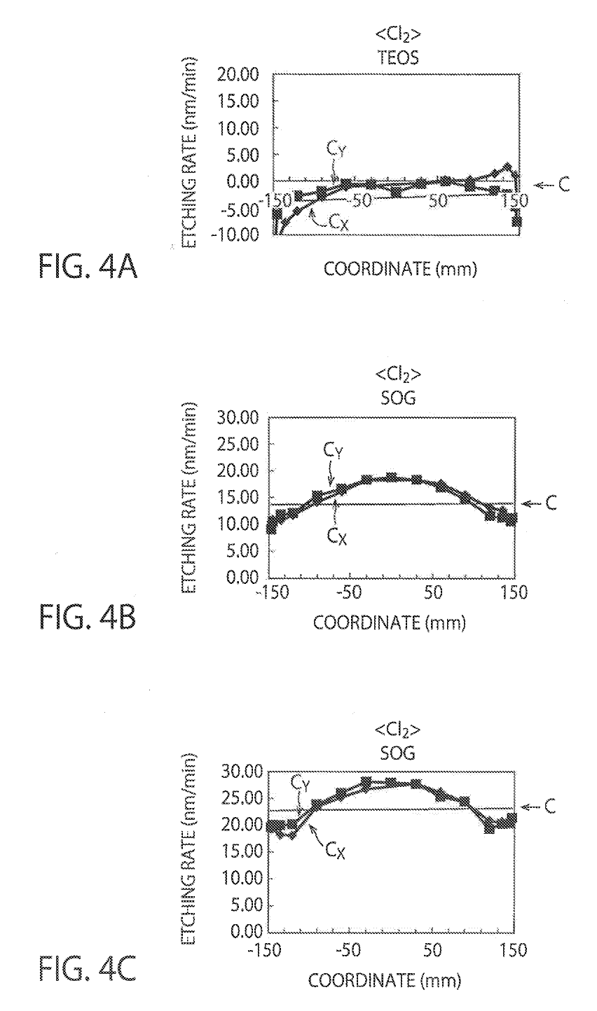

FIGS. 4A to 4C are graphs illustrating etching rates in a case where a Cl₂ gas was used in the first embodiment.

FIGS. 4A to 4C illustrate the etching rates of a TEOS film whose carbon content was several atom % (less than 5 atom %), a SOG film whose carbon content was 7 atom %, and a SOG film whose carbon content was 12 atom %, respectively. From FIGS. 4A to 4C, it is apparent that the etching rate of the silicon oxide film increases as the carbon content of the silicon oxide film increases.

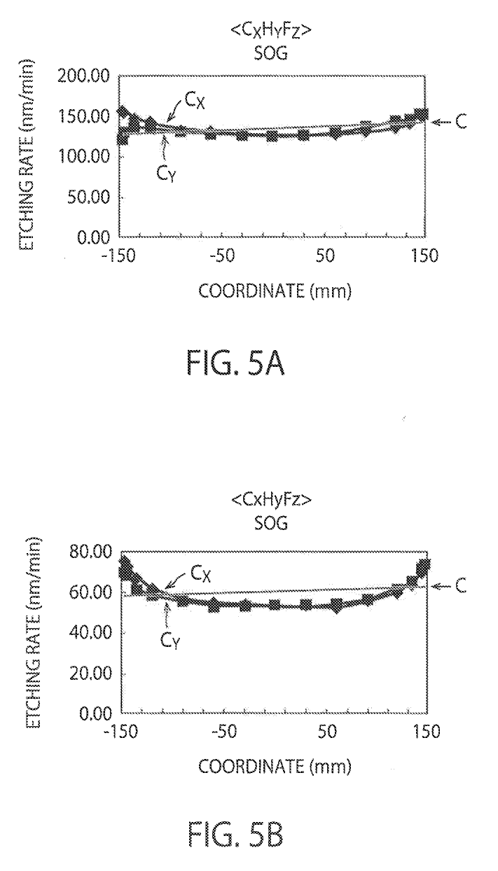

FIGS. 5A and 5B are graphs illustrating etching rates in a case where a CF-based gas was used in the first embodiment.

FIG. 5A illustrates the etching rate of a SOG film whose carbon content was 9 atom %. FIG. 5B illustrates the etching rate of a SOG film whose carbon content was 16 atom %. In FIGS. 5A and 5B, the etching rate of the silicon oxide film decreases as the carbon content of the silicon oxide film increases.

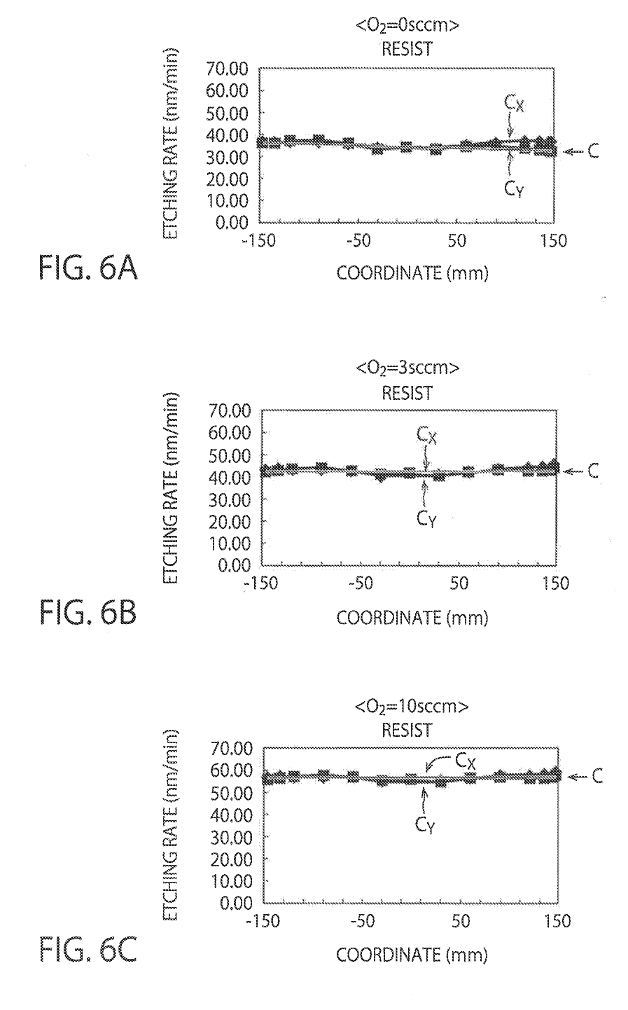

FIGS. 6A to 6C are graphs illustrating etching rates in a case where an O₂ gas was used with a HBr gas in the first embodiment.

FIG. 6A illustrates the etching rate in a case where the flow rate of the O₂ gas is 0 sccm. FIG. 6B illustrates the etching rate in a case where the flow rate of the O₂ gas is 3 sccm. FIG. 6C illustrates the etching rate in a case where the flow rate of the O₂ gas is 10 sccm. The etching targets in FIGS. 6A to 6C were resist films. From FIGS. 6A to 6C, it is apparent that the etching rate increases as the flow rate of the O₂ gas increases in the case where the resist film is etched by using the mixed gas containing the HBr gas and the O₂ gas.

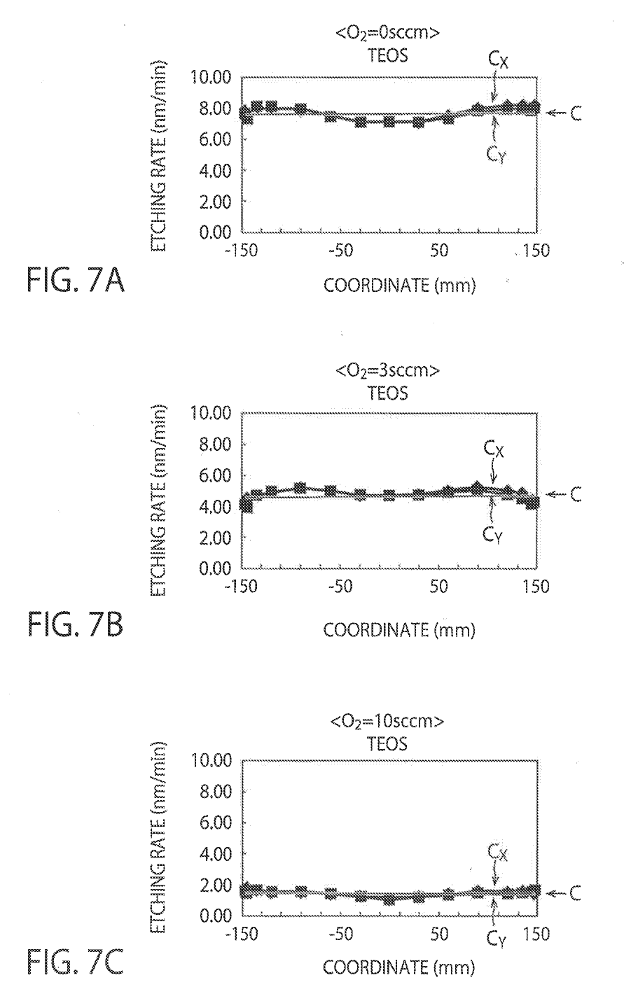

FIGS. 7A to 7C are graphs illustrating etching rates in a case where an O₂ gas was used with a HBr gas in the first embodiment.

FIG. 7A illustrates the etching rate in a case where the flow rate of the O₂ gas was 0 sccm. FIG. 7B illustrates the etching rate in a case where the flow rate of the O₂ gas was 3 sccm. FIG. 7C illustrates the etching rate in a case where the flow rate of the O₂ gas was 10 sccm. The etching targets in FIG. 7A to FIG. 7C were TEOS films. From FIGS. 7A to 7C, it is apparent that the etching rate decreases as the flow rate of the gas increases in the case where the TEOS film is etched by using the mixed gas containing the HBr gas and the O₂ gas.

When the flow rate of the O₂ gas increases, the amount of the HBr gas decreases in an etching chamber where the TEOS film is etched. Therefore, the results in FIGS. 7A to 7C indicate that when the flow rate of the O₂ gas increases, the amount of the HBr gas in the etching chamber decreases and therefore the etching rate decreases. Therefore, the results indicate that the HBr gas contributes to the etching of the TEOS film and that the etching rate of the TEOS film can be adjusted by the flow rate of the O₂ gas.

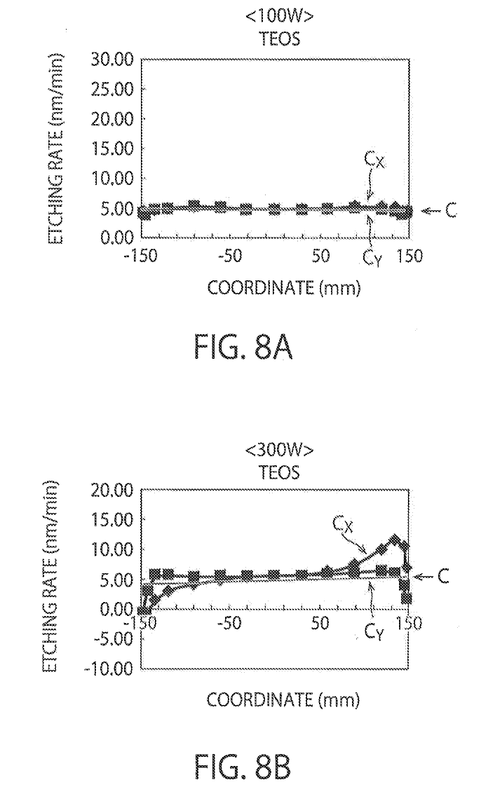

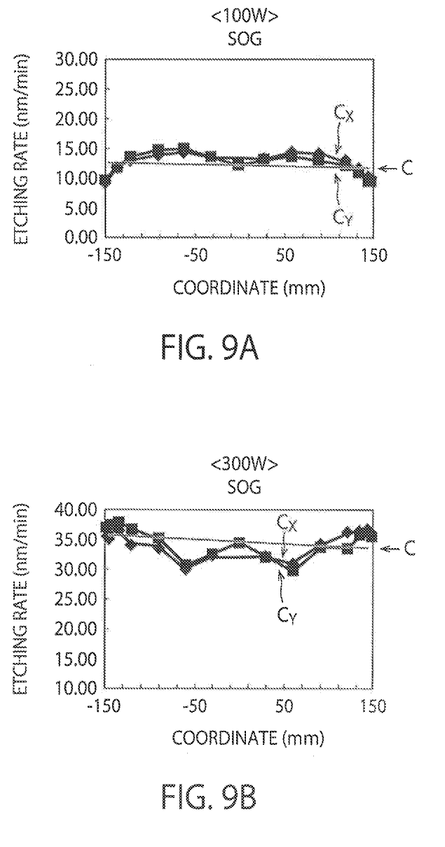

FIGS. 8A to 9B are graphs illustrating relation between ion energy and etching rates in the first embodiment.

The etching targets in FIGS. 8A and 8B were TEOS films whose carbon content was several atom %. FIG. 8A illustrates the etching rate in a case where the ion energy in etching was 100 W. FIG. 8B illustrates the etching rate in a case where the ion energy in etching was 300 W.

The etching targets in FIGS. 9A and 9B were SOG film whose carbon content was 7 atom %. FIG. 9A illustrates the etching rate in a case where the ion energy in etching was 100 W. FIG. 9B illustrates the etching rate in a case where the ion energy in etching was 300 W.

For example, when the TEOS film in FIG. 8A is used as the sidewall film 6 and the SOG film in FIG. 9A is used as the mask layer 4, the etching selection ratio that is approximately 2 or more is realized in the etching of FIG. 2B.

Meanwhile, when the TEOS film in FIG. 8B is used as the sidewall film 6 and the SOG film in FIG. 9B is used as the mask layer 4, the etching selection ratio that is approximately 6 is realized in the etching of FIG. 2B.

This makes it clear that the etching selection ratio increases when the ion energy is increased in the process of FIG. 2B.

As described above, the mask layer 4 (first silicon oxide film) having the first carbon content is etched by using, as a mask, the sidewall film 6 (second silicon oxide film) having the second carbon content in the present embodiment. This etching is performed by using the gas containing bromine or chlorine in the present embodiment.

Accordingly, the mask layer 4 out of these silicon oxide films can be selectively etched according to the present embodiment. Therefore, the present embodiment makes it possible to transfer the sidewall patterns 6a such that the dimensions thereof are excellently controlled.

### Second Embodiment

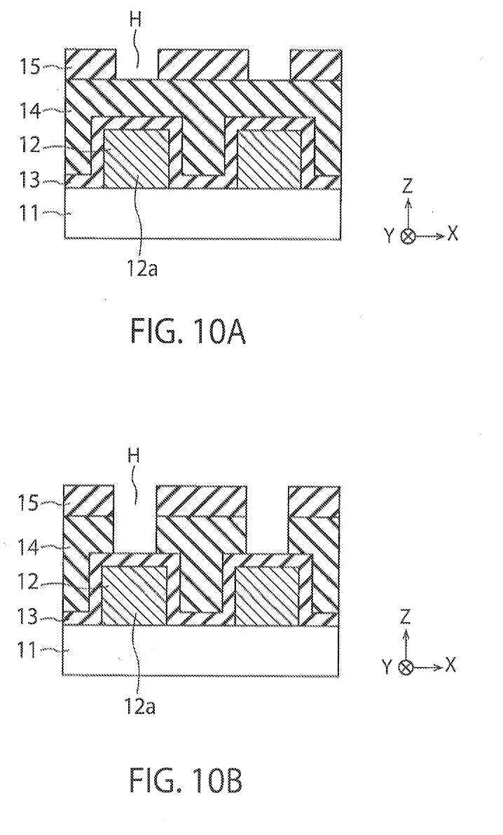

FIGS. 10A and 10B are sectional views illustrating a method of manufacturing a semiconductor device of a second embodiment. In the present method, a low dielectric constant film (low-k film) is etched by using the change in etching rate due to the change in carbon content. The low-k film is an insulator having a lower dielectric constant than a normal silicon oxide film.

First, a interconnect layer 12 including interconnects 12a is formed on a substrate 11 (FIG. 10A). Details of the substrate 11 are similar to those of the substrate 1. The interconnect layer 12 of the present embodiment is formed on the substrate 11 through an inter layer dielectric and the like.

Next, a first process target film 13, a second process target film 14 and a mask layer 15 are sequentially formed to cover the interconnect layer 12 on the substrate 11 (FIG. 10A). The first process target film 13 of the present embodiment is a silicon oxide film having a first carbon content. The second process target film 14 of the present embodiment is a silicon oxide film having a second carbon content higher than the first carbon content. Therefore, the second process target film 14 of the present embodiment contains carbon higher in concentration than the first process target film 13. An example of the second process target film 14 of the present embodiment is a silicon oxide film as the low-k film. Openings H are then formed in the mask layer 15 by lithography and etching (FIG. 10A).

The second process target film 14 is then etched by using the mask layer 15 as a mask and using the first process target film 13 as an etching stopper (FIG. 10B). As a result, the openings H penetrate the second process target film 14, and the bottom faces of the openings H reach the upper faces of the first process target film 13 which are positioned above the interconnect layer 12.

The etching in FIG. 10B is performed using a gas containing bromine or chlorine. As mentioned above, in the case where a silicon oxide film is etched using the gas containing bromine or chlorine, the etching rate of the silicon oxide film increases as the carbon content of the silicon oxide film increases. Therefore, in the etching of FIG. 10B, the second process target film 14 (second silicon oxide film) can be selectively etched with the first process target film 13 (first silicon oxide film) being as a stopper. The reason is that the second carbon content is higher than the first carbon content and the etching rate of the second process target film 14 is higher than the etching rate of the first process target film 13.

In this way, the second process target film 14 out of these silicon oxide films can be selectively etched according to the present embodiment.

While certain embodiments have been described, these embodiments have been presented by way of example only, and are not intended to limit the scope of the inventions. Indeed, the novel methods described herein may be embodied in a variety of other forms; furthermore, various omissions, substitutions and changes in the form of the methods described herein may be made without departing from the spirit of the inventions. The accompanying claims and their equivalents are intended to cover such forms or modifications as would fall within the scope and spirit of the inventions.

1. A method of manufacturing a semiconductor device, comprising:
forming a first silicon oxide film having a first carbon content above a substrate;
forming a second silicon oxide film having a second carbon content different from the first carbon content on the first silicon oxide film; and
selectively etching the first or second silicon oxide film by using a gas containing bromine or chlorine.

2. The method of claim 1, wherein
the second carbon content is lower than the first carbon content, and
the first silicon oxide film is etched in the selective etching by using the second silicon oxide film as a mask.

3. The method of claim 2, further comprising:
forming a first pattern on the first silicon oxide film; and
forming a second pattern formed of the second silicon oxide film on a side face of the first pattern,
wherein the first silicon oxide film is etched by using the second pattern as the mask.

4. The method of claim 3, wherein the first pattern is a resist pattern.

5. The method of claim 2, wherein the first silicon oxide film is formed by applying a coating solution on a carbon film.

6. The method of claim 5, wherein the first silicon oxide film contains carbon dissolved from the carbon film into the first silicon oxide film.

7. The method of claim 5, wherein the first silicon oxide film and the carbon film are etched in the selective etching by using the second silicon oxide film as the mask.

8. The method of claim 5, wherein the second silicon oxide film is formed by chemical vapor deposition (CVD).

9. The method of claim 1, wherein
the second carbon content is higher than the first carbon content, and
the second silicon oxide film is etched in the selective etching by using the first silicon oxide film as a stopper.

10. The method of claim 9, wherein the second silicon oxide film is a low-k film.

11. The method of claim 1, wherein one of the first and second carbon contents is less than 5%, and the other of the first and second carbon contents is 5% or more.

12. The method of claim 11, wherein the one of the first and second carbon contents is 1% or less.

13. The method of claim 11, wherein the other of the first and second carbon contents is 10% or more.

14. The method of claim 1, wherein the gas containing bromine or chlorine contains a hydrogen bromide gas, a hydrogen chloride gas, a bromine gas or a chlorine gas.

15. The method of claim 1, wherein the selective etching is performed by forming plasma from the gas containing bromine or chlorine.

16. The method of claim 1, wherein the selective etching is performed using a mixed gas that contains the gas containing bromine or chlorine and a C_{X}H_{Y}F_{Z} gas, where C denotes carbon, H denotes hydrogen, F denotes fluorine, X is an integer of one or more, Y is an integer of zero or more and Z is an integer of one or more.

17. The method of claim 16, wherein a ratio of the C_{X}H_{Y}F_{Z} gas in the mixed gas is 5% or less.

18. The method of claim 1, wherein the selective etching is performed by using a mixed gas that contains the gas containing bromine or chlorine and an oxygen gas.

19. The method of claim 18, wherein the selective etching is performed by adjusting an etching rate of the first or second silicon oxide film by a flow rate of the oxygen gas.

20. The method of claim 19, wherein the etching rate of the first or second silicon oxide film decreases with increasing the flow rate of the oxygen gas.
